(19) United States
(12) Patent Application Publication
(10) Pub. No.: US 2006/0162960 A1
(43) Pub. Date: Jul. 27, 2006

(54) SYSTEM FOR DETERMINING PRINTED CIRCUIT BOARD PASSIVE CHANNEL LOSSES

(75) Inventors: Eric W. MONTGOMERY, Springfield, MO (US); Robert W. SPEER, Springfield, MO (US)

Correspondence Address: MARSTELLER & ASSOCIATES, P.C., PO BOX 803302, DALLAS, TX, 75380-3302, US

(73) Assignee: LITTON SYSTEMS, INC., Los Angeles, CA (US)

(21) Appl. No.: 11/306,088

(22) Filed: Dec. 15, 2005

Related U.S. Application Data
(60) Provisional application No. 60/593,163, filed on Dec. 16, 2004.
(60) Provisional application No. 60/596,400, filed on Sep. 20, 2005.

(51) Int. Cl. H05K 1/11

(52) U.S. Cl. 174/262

(57) ABSTRACT

A method for determining passive channel losses for passive channel structures (48) in electronic circuit boards includes selecting parameters from the list including driver/receiver device current and device time or device voltage and device time data, electrical environment variables, electrical data for materials used, electrical data for via structures, copper trace electrical data, connector electrical data, schematic design data and similar selected parameters. At least one selected parameter is inputted into a processor (62) for generating an output (26) based upon calculating desired output characteristics of the desired channel structure (48). The output (26) from the calculation is correlated with previously measured data for generating a resulting output planning a desired channel structure (48).

### CROSS REFERENCE TO RELATED APPLICATIONS

This application claims the benefit of U.S. Provisional Application Ser. No. 60/593163, filed Dec. 16, 2004, entitled SYSTEM FOR CONVERTING CIRCULAR VIAS IN CIRCUIT BOARDS, and U.S. Provisional Application Ser. No. 60/596400, filed Sep. 20, 2005, entitled SYSTEM FOR DETERMINING PRINTED CIRCUIT BOARD PASSIVE CHANNEL LOSSES.

### BACKGROUND OF THE INVENTION

1. Technical Field

The invention relates to the field of printed circuit boards and more particularly to a determining the shape or size of conductors formed in a printed circuit board to yield least signal losses and highest signal reliability.

2. Background Art

Conventionally, in determining optimal channels formed in electronic circuits, a problem of conversion of circuit information into geometric configuration information has been regarded as important. Because any distinct index from the viewpoint of signal reliability has not been given, problems that a channel formed in a circuit board not optimally functioning have occurred.

For developing circuit board channel structure that operates optimally, experimental knowledge is required. As a result, there is a wide difference between a less experienced engineer and a well-experienced engineer. However, even if well experienced, the engineer cannot always design a circuit channel that operates optimally.

While the above cited references introduce and disclose a number of noteworthy advances and technological improvements within the art, none completely fulfills the specific objectives achieved by this invention.

### SUMMARY OF INVENTION

In accordance with the present invention, a method for determining passive channel electrical acceptance in an electronic circuit board includes selecting loss parameters from the list including driver and receiver device current and device time or device voltage and device time data, dielectric materials loss parameters including dielectric material structure loss parameters, via structures loss parameters, copper trace loss parameters including copper structure loss parameters, connector loss parameters, environmental loss parameters, schematic design data and similar selected parameters. The loss parameters may generally include variable such as scattering parameters that may or may not include phase data, measured or interpolated data from measured results. At least one of the selected parameters is inputted into a calculator for generating an output based upon calculating output characteristics of the desired channel structure. The output from the calculation may or may not be correlated with previously measured data for generating resulting output for correlating the planning of the desired channel structure.

An objective of this present invention is to provide all pertinent signal propagating high speed passive channel structure data developed by the present method thus reducing the signal degradation caused by the passive channel transmission components and reducing the time for typical passive channel electrical solution.

The passive channel is defined as all of the components that affect signal propagation and degrade signal strength from the output of an active device or transmitter typically found on a daughter card to the input of the active device or receiver again typically found on a daughter card. Such components may be categorized as being Primary lossy components or Secondary lossy components.

These and other objects, advantages and features of this invention will be apparent from the following description taken with reference to the accompanying drawings, wherein is shown the preferred embodiments of the invention.

### BRIEF DESCRIPTION OF DRAWINGS

A more particular description of the invention briefly summarized above is available from the exemplary embodiments illustrated in the drawings and discussed in further detail below. Through this reference, it can be seen how the above cited features, as well as others that will become apparent, are obtained and can be understood in detail. The drawings nevertheless illustrate only typical, preferred embodiments of the invention and are not to be considered limiting of its scope as the invention may admit to other equally effective embodiments.

The figures below are for illustration of the passive channel evaluation process.

FIG. 1 depicts a passive signal channel in an electronics device.

FIG. 2 is a schematic flow chart of the operations of the present invention.

FIG. 3 is a pictorial of the process variables flow for the fabrication process.

FIG. 4 is a Printed Circuit cross section showing the conductor and dielectric material.

FIG. 5 is a graph illustrating function development.

FIG. 6 is a graph showing function summing results for one exemplary characteristic.

FIG. 7 is a schematic diagram of one embodiment of the present invention utilizing a central processing unit.

### DETAILED DESCRIPTION

So that the manner in which the above recited features, advantages, and objects of the present invention are attained can be understood in detail, more particular description of the invention, briefly summarized above, may be had by reference to the embodiment thereof that is illustrated in the appended drawings. In all the drawings, identical numbers represent the same elements.

The present invention includes a system and method referred to as the Algorithm for Passive Channel Evaluation system that translates manufacturing tolerance and environmental factors into changes in the primary transmission line components and thus channel performance.

The via structure is evaluated to determine the via stub, via capacitance and the via impedances affecting on signal quality. The present method defines the critical components affecting of the via structures and thus affecting “s_parameters” or scattering parameters.

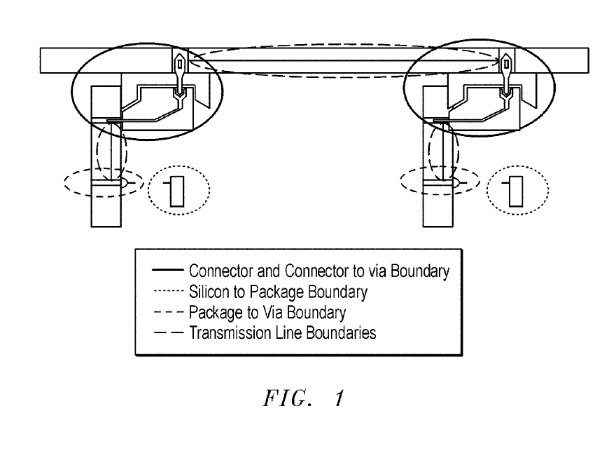

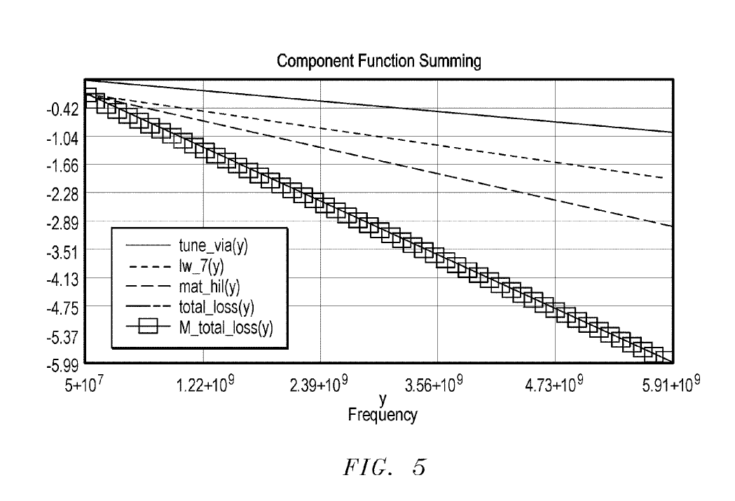

FIG. 1 shows the passive channel 10 formed with a printed circuit board (PCB) 16 for communicating a desired signal subject to loss or signal degradation. The passive channel 10 includes the connectors 12 establishing an electrical connection passing signals between the PCB 16 and a daughter card 14. Note that the passive channel 10 does not include the active devices found on a daughter card 14. The connector component of the passive channel algorithms of the present invention will not be directly addressed herein, but may be added to expand upon or further refine the solution or results of the present method. Generally, an interconnect will be included in all passive channel algorithm solutions. FIG. 4 illustrates a cross section the passive channel from a daughter card 14 to a backplane 16 and terminating on the backplane or main PCB.

Each partitioned component, as shown in FIG. 1, of the passive channel 10 generally is either a Primary, Secondary and Additional electrical component that may result in a parameter or value that may be summed in the Passive Channel Algorithm of the present invention.

A loss component value, which is all combination of scattering parameters with or without phase data of each Primary, Secondary, and Additional transmission component, is measured and optionally stored as a table file or a text file or other comparable method.

The Primary electrical components in order of loss magnitude resulting in signal degradation are:
1. Dielectric Materials
2. Via Structures
3. Copper Conductors

The Secondary electrical components or process variables that affect the primary electrical components listed above include:
1. Dielectric press thickness
2. Copper height
3. Copper width
4. Via registration
5. Dielectric Constant and Dissipation Factor

Some additional electrical components that may affect the primary electrical components or secondary electrical components are:
1. Cooper Roughness
2. Fiber bundle Distribution
3. Environmental Effect

The present method for determining via structure component value scattering parameters for optimal design of the via structure in an electronic circuit board includes selecting parameters from the list including driver/receiver device current and device time or device voltage and device time data, electrical environment variables, electrical data for materials used, electrical data for via structures, copper trace electrical data, connector electrical data, schematic design data and similar selected parameters. At least one of the selected parameters is inputted into a calculator or a known computing system with programmable instructions for generating an output based upon calculating desired output characteristics of the desired channel structure. The output from the calculation is correlated with previously measured data for generating a resulting output used in the optimal planning a desired channel structure.

The mathematics for each of the key parameters is detailed in the following information.
1. Electrical Critical length of the Via or Via Stub.
2. Critical Frequency of the Via or Via Stub.
3. Receiver Sensitivity.
4. Returned voltage and how the Standing Wave Ratio affects the received voltage.
5. Via “Quality” or Q.
6. Bandwidth of the via referencing critical frequency.
7. Converting clearances using math-cad or other known mathematical assisting computer program.

Associated documents may include:
1. Via tuning;
2. Defining critical length and critical frequency of vias; and
3. Via components.

### PREFERRED METHOD

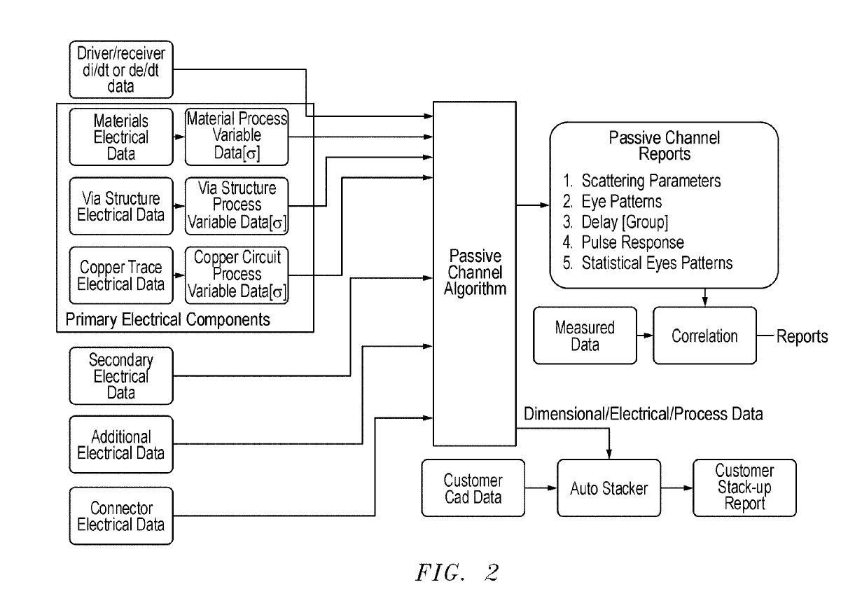

In the flow chart of FIG. 2, the auto stacker 20 is a tool that automatically develops printed circuits boards multi-layered stack from a database of dielectric materials and conductor layers. Although the auto stacker 20 is considered to not be a part of the passive channel algorithm, nevertheless, the auto stacker 20 is shown because the central or main passive channel algorithm 22 may provide data to the auto stacker 20.

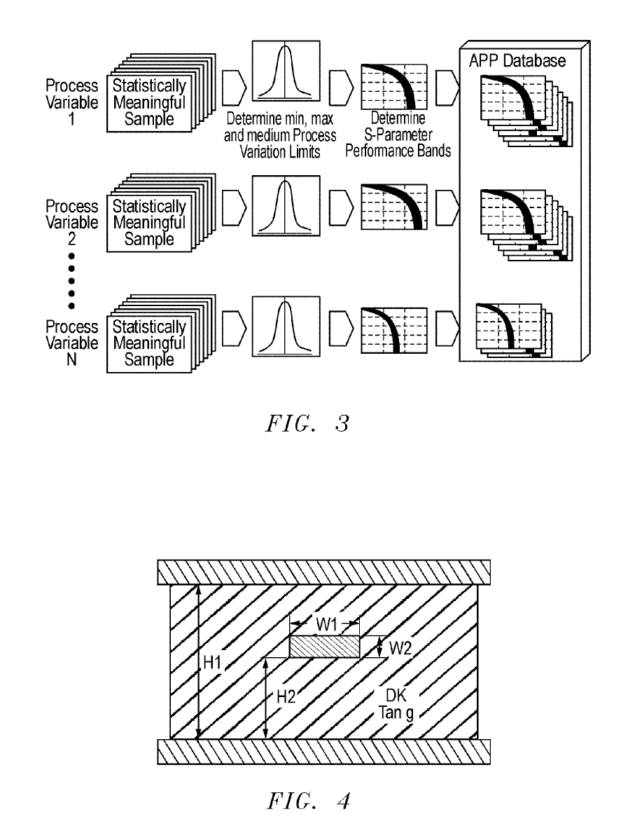

Scattering parameters 24 are analog electrical parameters that define the scattering of voltages in a transmission line. These scattering voltages may include reflected voltages, coupled voltages or voltage that pass through the passive channel 10. See FIG. 3.

There are a large number of different key parameters that affect the performance of an exemplary 10 Gbps passive channel via structure formed in a printed circuit board 16. These parameters may be grouped into a number of areas for analysis. The method of calculating via structures involves the data defined by the dimensions controlling the electric and magnetic fields.

Such method steps include:
Identifying the Key Parameters
Proving correlation between measured and modeled/simulated data.
Establishing a relationship between the Key Parameters and the Channel S-Parameters (scattering parameters) using math, simulation or measurement
Documenting the possible variation in Key Parameters due to the manufacturing/assembly process
Creating a priority list showing the parameters with greatest impact
   Mathematical evaluation of via clearances using capacitance

For the present analysis, via capacitance preferably must be known. This may be done using a known field solver, a static equation with all dimensions defines or by calculating the via capacitance value using device voltage and device time (a differential equation) extracted from measured data.

Once the capacitance of the via structure is understood, several methods to predict the impedance of the via structure may be utilized. These methods include:

1. Basic impedance equations

2. Field solvers

3. Measured reflections.

Further Mathematical evaluation of via clearances

For this portion of the present invention, critical length and critical frequency should be known. Typical critical length is ¼ λ at the frequency or frequencies of interest. Smaller increments or fractions of wave lengths [⅛ λ or 1/10 λ] may be considered depending on the application.

¼ λ (wavelengths) are critical because of the voltage or power that often occurs at these locations along the signal path. The possibility of a significant voltage occurring or appearing at a critical length along the transmission path, such as the end of a via structure, may be a significant factor. However, if a null point occurs at the critical length, no voltage generally is returned. Understanding the electrical length, critical length and critical frequency is very important for a typical circuit designer to ensure signal integrity and cost effectiveness.

The mathematics for the via structure

The variables and mathematics were defined for a known mathematical modeling and analysis computer program, such as Mathcad. The equations may be used with other mathematics programs. However, the format will require changes.

Defining Copper Conductors process and feature variables affecting signal strength

For a copper conductor the material's electrical data and conductor's electrical data are addressed together in a following section herein.

With reference particularly to FIG. 4, the components affecting the electrical and magnetic field are illustrated. The key physical parameters of the strip line construction are:
(1) H1—the height 40 between the reference planes 42 and 44 of the printed circuit board
(2) H2—the height 46 up to the conductor 48 from the lower reference plane
(3) W1—the conductor width 50
(4) W2—the conductor height or thickness 52
(5) DK—Dielectric constant of the layer 54 between the upper plane 42 and the lower plane 44
(6) Tan g—the loss tangent for layer 54

Where:

The variable H1 is used for all dielectric thickness data. H1 is the total height of the electro-magnetic field. To determine H2, H1 may be divided by 2.

Line width is selected by the user or is a supplied measurement from a sensor or other means to determine this characteristic.

The impedance specification for all parameters is assumed for explanatory purposes of the present invention to be 50 ohm+−10%. This specification is used to calculate the impedance standard deviation.

The trapezoidal effect along a copper trace may be assumed to be a constant for purposes of the description of the present invention, but may vary depending on the specific application of the present invention.

Defining each of the variables in the electric field surrounding the conductor 48 and including the conductor that affect the electrical performance can be done by defining the process standard deviation of each of the desired variables. These variables are defined and provided as a variable to the central algorithm 22 of the present invention.

TABLE 1
Line width equal to or greater than 5 mils

| | | | Standard | |
|---|---|---|---|---|
| Upper limit | Lower limit | Mean | Deviation | Function |
| 7.25 | 6.25 | 7 | .33 | TBD |

TABLE 2
Impedance Changes as a function of Table 1

| | | | Standard | |
|---|---|---|---|---|
| Upper limit | Lower limit | Mean | Deviation | Function |
| 51.8 | 47.3 | 49.84 | 1.418 | TBD |

Note:
the data in table 1 and table 2 above are for one frequency only (1 Ghz for example).
Each function derived for the passive channel solution may provide desired scattering parameters for all desired frequencies of interest.

Defining the range of a process variable or the Secondary and Additional Functions, a normal standard distribution equation is generally used.

Equations for Normal Standard Distribution:

$$\begin{matrix}x := [ ( {μ}_{df1c} ) - 6 \cdot \frac{σ1}{\sqrt{N}} , ( {μ}_{df1c} - 6 \cdot \frac{σ1}{\sqrt{N}} ) + \\ 0.1 \cdot \frac{σ1}{\sqrt{N}} \cdot {μ}_{df1c} + ( 6 \cdot \frac{σ1}{\sqrt{N}} ) + \\ \\ f norm ( {μ}_{df1c} , σ11 , x ) := \\ \frac{1}{\frac{σ11}{\sqrt{N}} \cdot \sqrt{2 \cdot π}} \cdot {ⅇ}^{- \frac{1}{2} \cdot {[ \frac{( x - {μ}_{df1c} )}{( \frac{σ11}{\sqrt{N}} )} ]}^{2}}\end{matrix}$$

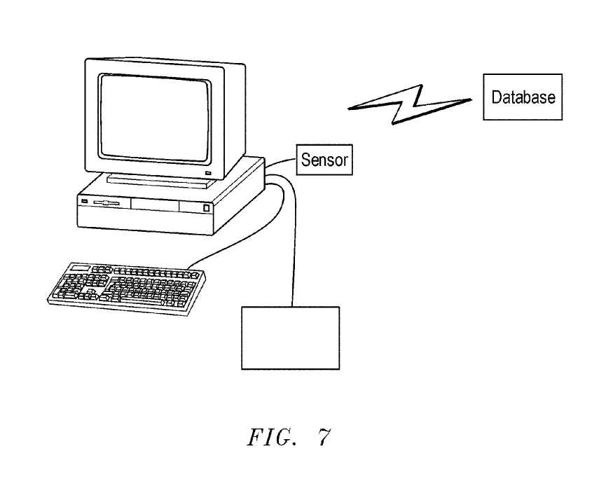

Referring now to FIG. 7, the present invention generally includes a central processing unit (CPU) 62 that provides the computing power helpful in calculating the design parameters.

A typical embodiment of the present invention includes a known central processing unit (CPU) module 62 with a micro processor. Computer software is installed with the microprocessor, which software incorporates processing steps following the method of the present invention. The CPU 62 generally has more on or more modes of data input 64 operably connected to the CPU. Such data input means may include a keyboard or keypad 66 for manually entering or keying in parameter data or other sensors 68 monitoring desired physical characteristics of the device to the tested D. The CPU 62 also is operably connected with a database module 70 with signals 72 being passed between the CPU 62 and the database module 70. The database module 70 includes the lookup table as described above and provides parameters to the CPU 62 and algorithm in response to queries from the CPU 62.

After the CPU 62 and included software processes the inputted information, an output signal is communicated to one or more output units or modules 74, such as a display, printer, or plotter. The user may review the information calculated by the CPU 62.

Optionally the present method may include iterative steps whereby the output 26 generated from the main algorithm 22 may be stored and also used in a repetitive series of steps in which the input parameters are marginally changed to determine whether a more optimal output 26 result is reached.

Device Under Test [DUT] used to measure the material losses, environmental variable losses and line-width variable and fixed losses

The following information pertained to the DUT used for exemplary purposes:
(1) 16 inch transmission lines [single ended and differential]
(2) Trace widths are 10 mils and 8 mils
(3) Trace height is 1 oz or 1.2 mils
(4) Launch and receive connectors are SMT, SMA's.

FIG. 4 exemplifies a device under test.

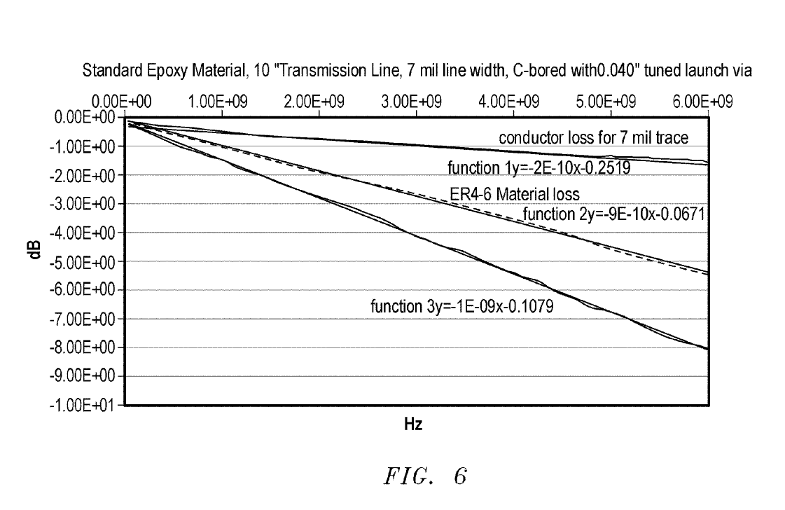

With reference to FIG. 5, the following describes the data shown in the graph:
(1) -6_means the board was tested at room temperature with no forced humidity.
(2) -6_{—}85 means the board was tested at 85 c
(3) -6_humid means the board was tested after the temperature and humidity cycle.

Additional environmental testing that will result in functions for the passive channel algorithm will include:
(1) Passive channel with via structures counter-bored
(2) Passive channel with counter boring, connectors and daughter cards.
(3) Temperature and humidity effects on copper conductors

### ENVIRONMENTAL CONSIDERATIONS [additional electrical components]

Description of temperature and humidity section:

The following basic environmental electrical data may be used to determine if signal integrity issues exist relating to the environmental conditions of the Device under Testing (DUT). The environmental parameters are:

Scattering Parameters and Time Domain Transmission {TDT} and trace resistance measured at room temperature and room humidity.
(1) Humidity=40%
(2) Temperature=23 c

Scattering Parameters and TDT and trace resistance measured at temperature at elevated temperature and room humidity.
(1) Humidity=40%
(2) Temperature ramped to 90 c

Scattering Parameters and TDT and trace resistance measured at constant humidity and temperature cycle.
(1) Constant humidity=90%
(2) Temperature cycle is room temp to 90 c
(3) Cycle time was 4 hrs
(4) Cycle duration was 7 days.

Test device for assigning material and line width losses

The line width variables are assigned in much the same way. Once the material loss is assigned, that value of loss is subtracted from each line width measured thus providing a line width loss for each line width measured. Interpolation is used to transpose the measured line width loss data to line width loss data at ¼ mil increment, by way of example.

These interpolated scattering parameters are determined by the ratio between larger copper conductor widths.

This ¼ mil increment provides the process variables scattering parameters for all copper conductor widths.

Once all measured and interpolated data is collected in the data base 70, functions are developed for each Primary Electrical Component and all variations of the component, Secondary Electrical Component and all variation of the component and each Additional Electrical Component and all variations of the component.

The database 70 generally includes the functions that calculate the scattering parameters for each material, conductor, via structures, along with secondary and additional components, and further includes the measured data that is used to derive all functions. Once the functions are derived, the measured data may no longer be needed. The sampled data can be stored as desired. Generally, the database module 70 consists of a large list of functions with each function representing a component. For example, if one needs to design a printed circuit board (PCB) using the design or sampled characteristics of low loss material, via structures that finish at 18 mils, the layer count is 30 layers, the conductor width is 7 mils, then the main algorithm 22 of the present invention or the CPU 72 would call from the data 70 a 7 mil functions, a low loss material function, a 18 mil, 30 layer via function, and sum them in the passive channel algorithm. The algorithm 22 of the present invention will then call or alternatively, the operator can also call), the process data and essentially arrive at each solution relative to the process variable or the scattering parameters. Scattering parameter summing is generally illustrated herein.

Illustrating the techniques used to assign the loss to the Dielectric Material, subtract the measured loss of the conductor (for example, line width×line height) from total loss of a transmission line without via structures or the affects of via structures.

The results are the loss (such as the scattering or s_parameters) assigned to the dielectric material type.

With the conductor loss known, the dielectric loss of each material can be assigned.

From the measured data, one may develop the function. Once functions are defined for each Primary, Secondary and Additional electrical component of the passive channel, The Algorithm 22 for Passive Channel Evaluation or application of the present invention is formulated by summing two or more functions or equations. Although these equations can be used independently to provide a single passive component loss value such as the dielectric material loss, these equations are more useful when summing two or more channel components thus providing a passive channel solution for high-speed transmission.

To illustrate the method of extracting function from measured data, one may refer to FIG. 6. A set of data for each component measured is graphed and the function is attained.

For each of the Primary, Secondary and Additional components, one may define the relationship between functions as a Primary Variable Equations, which is used as the foundation equations and then summed with other primary equations, and/or Secondary Variable Equations, and/or the Additional Variable Equations. Each equation's calculated loss of the component per inch or other unit of length of passive channel length or in the case of a via structure, per via.

For material loss, a primary equation that calculates a single material scattering parameter is:
Mat_hi1(y)=(mat_k_hi1 * y)−mat_slope_hi1

Where mat_hi1 (y) is the dielectric material being defined (hi1 indicates high loss of material #1), mat_k is a material constant derived in the function solution, y is the frequencies applied to the passive channel and mat_slope_hi1 defines the slope of the measured data. The solution is the Scattering parameter 12 (which is the scattering parameter for through channel loss) for a specific material relative to the applied frequency. To add other passive channel “lossy” components, one may simply sum the Secondary Components or Additional Components with the Primary Components, such as the material, vias, conductors.

All equations or functions are summed in the same fashion as the primary equations. FIG. 5 shows function summing as an illustration of the method used to solve a high-speed channel solution.

FIG. 5 illustrates summing of each primary component function and a correlation to the measured total loss. This shows the passive channel algorithm summing techniques. In essence the passive channel algorithm draws functions of each primary, secondary or additional electrical components from a data bank and algebraically sums them.

To calculate a single via s_parameter:
tune_via(y)=(via_k_{—}16 * y)+via_slope_{—}16

To calculate a single width s_parameter:
1w_{—}7(y)=(1w_k_{—}7* y)+1w_slope_{—}7

To calculate a single material s_parameter:
mat_hi1(y)=(mat_k_hi1 * y)+mat_slope_hi1

To calculate a channel s_parameter:
total_loss(y)=(tune_via(y)+1w_7(y))+mat_hi1(y)

To calculate the measured total loss s_parameter:
M_total_loss(y)=(M_total_k * y)+M_total_slope

The via loss is shown in function tune_via (y); the line width loss is shown in function 1w_7(y); the material loss is shown in function mat_hi1 (y) where hi1 is high loss material 1. To attain total loss, these functions are summed.

The final function shown in FIG. 5 is the measured loss of the passive channel. This measured loss is compared in the graph to total_loss (y) or the passive channel algorithm solution. In this illustration, total_loss (y) equals M_total_loss (y) (or the Measured total loss) proving the validity if the passive channel evaluation algorithm process.

The Passive Channel Algorithm database 70 includes all scattering parameters and math functions for the Primary, Secondary and Additional Electrical Components identified in this disclosure. This data is accessed by the Passive Channel Algorithm 22 of the present invention by requesting, through software or attaching manually, a specific Printed Circuit Board (PCB) material, via structure and conductor or conductors cross sections. Process variables, Secondary Electrical Components, in the database 70 are also attached to the Primary Electrical Components as needed. Additional Electrical Components may be included at the discretion of the electrical designer or the Passive Channel Algorithm operator or user.

The uniqueness of this solution is not just in the primary functions derived from the measured transmission line components but in the calculated primary functions, secondary functions and additional functions that provide channel solutions including printed circuit board process variables, material and copper structure variables and environmental variables.

The present invention provides a channel solution faster than other known simulation tools. Design characteristic and other information is derived for a high speed information line channel through daughter-cards, backplanes, drivers, receivers and the like.

The foregoing disclosure and description of the invention are illustrative and explanatory thereof, and various changes in the size, shape and materials, as well as in the details of the illustrated construction may be made without departing from the spirit of the invention.

What is claimed is:

1. A method for determining passive channel component or structure values in the passive channel of a electronic circuit board, the method comprising:
a first step of selecting parameters from a list including driver/receiver device voltage and device time data, electrical environment variables, electrical data for materials used, electrical data for via structures, copper trace electrical data, connector electrical data, schematic design data, and other desired parameters;
a second step of inputting at least one of the selected parameters into a computing means for generating an output based upon calculating desired output characteristics of the desired channel structure; and
a third step of correlating the output from the calculation with previously measured data for generating a resulting output planning a desired channel structure.

2. The method of claim 1 wherein the selecting of parameters includes a database of selected parameters providing a desired characteristic for solution of the output planning for the desired channel structure in response to an input parameter.

3. The method of claim 1 further including displaying the output signal in a pre-selected display mode on an output means in communication with the CPU.

4. The method of claim 1 further including an input means in communication with the CPU for providing parameters to be inputted into the CPU.

5. The method of claim 4 wherein the input means includes a keypad for manually keying information.

6. The method of claim 4 wherein the input means includes sensors for electronically providing desired information.

7. The method of claim 1 further including a database module in communication with the CPU for providing parameters to be inputted into the CPU in response to queries by the CPU.

8. An apparatus for determining via structure in an electronic circuit board comprising:
means for selecting parameters from a list including driver/receiver device voltage and device time data, electrical environment variables, electrical data for materials used, electrical data for via structures, copper trace electrical data, connector electrical data, and schematic design data;
central processing unit (CPU) means for generating an output signal based upon calculating desired output characteristics of the desired channel structure using at least one of the selected parameters; and
means for correlating the output from the calculation with previously measured data for generating a resulting output planning a desired channel structure.

9. The invention of claim 8 further including an output means in communication with the CPU for displaying the output signal in a pre-selected display mode.

10. The invention of claim 8 further including an input means in communication with the CPU for providing parameters to be inputted into the CPU.

11. The invention of claim 10 wherein the input means includes a keypad for manually keying information.

12. The invention of claim 10 wherein the input means includes sensors for electronically providing desired information.

13. The invention of claim 8 further including a database module in communication with the CPU for providing parameters to be inputted into the CPU in response to queries by the CPU.
